(19) United States
(12) Patent Application Publication
(10) Pub. No.: US 2010/0258796 A1
(43) Pub. Date: Oct. 14, 2010

(54) ZINC OXIDE BASED SEMICONDUCTOR DEVICE AND METHOD OF MANUFACTURING THE SAME

(75) Inventors: Naochika Horio, Tokyo (JP); Mitsuyasu Kumagai, Tokyo (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: Stanley Electric Co., Ltd., Tokyo (JP)

(21) Appl. No.: 12/756,328

(22) Filed: Apr. 8, 2010

(30) Foreign Application Priority Data
Apr. 10, 2009 (JP) 2009-096485

(51) Int. Cl. H01L 29/24; H01L 21/04

(52) U.S. Cl. 257/43; 438/104

(57) ABSTRACT

Disclosed is a method of manufacturing a ZnO-based semiconductor device, the method includes a first metal layer formation step of forming a first metal layer on a p-type ZnO-based semiconductor layer in island-form and/or mesh-form; a heat treatment step of performing heat treatment of the first metal layer and the p-type ZnO-based semiconductor layer under an oxygen-free atmosphere to form a mixture layer comprising elements of the p-type ZnO-based semiconductor layer and the first metal layer at a boundary region therebetween while maintaining a metal phase layer on a surface of the first metal layer; and a second metal layer formation step of forming a second metal layer so as to cover the first metal layer and the exposed portions of the p-type ZnO-based semiconductor layer through openings of the first metal layer.

### BACKGROUND OF THE INVENTION

1. Field of the Invention

The present invention relates to a method of manufacturing a zinc oxide (ZnO) based (hereinafter, also referred to as ‘ZnO-based’) semiconductor device and, more particularly, to a ZnO-based compound semiconductor device having a contact electrode with high adhesion properties and good ohmic contact characteristics, as well as a method of manufacturing the same.

2. Description of the Related Art

ZnO is a direct transition type semiconductor having a band-gap energy of 3.37 eV at room temperature and is expected to be used as a material for a photoelectric device of a wavelength range from blue to ultraviolet. In particular, ZnO has the physical properties extremely suitable for a semiconductor light emitting device wherein an exciton binding energy is 60 meV and a refractive index is 2.0 (n=2.0). In addition, ZnO is not limitedly used in such light emitting diodes and/or light receiving diodes, but, may be employed in various devices including surface-acoustic wave (SAW) devices, piezoelectric devices, and the like. Moreover, ZnO as a raw material has the advantages that it is economical and is not harmful to the environment and human body.

It is well known that metal is poorly adhered to an oxide crystal and easily peels off or separated therefrom. In particular, semiconductors not containing oxygen (for example, AlGaAs, InAlGaP, InAlGaP, InGaN, etc.) do not have significant problems in terms of attachment and/or adhesion to an electrode metal. However, a ZnO semiconductor, which is a metal oxide, exhibits poor adhesion to metal materials such as gold (Au), silver (Ag), rhodium (Rh), platinum (Pt), palladium (Pd), etc. Therefore, a process for manufacturing a p-electrode had a problem in that a metal electrode formed on a ZnO film often peels off or separated therefrom. See, Japanese Laid-Open Patent Application No. 2003-110142 (hereinafter, also referred to as Patent Document 1) and Japanese Laid-Open Patent Application No. 2004-207440 (hereinafter, also referred to as Patent Document 2).

Furthermore, when heat treatment (e.g., alloying, sintering) is conducted after formation of an electrode in order to decrease contact resistance between a p-type ZnO layer and the electrode (i.e., to improve ohmic contact properties), there is a problem that peeling or separation of the electrode becomes pronounced. As such, with respect to an electrode of semiconductor device such as a semiconductor light emitting device, various manufacturing processes including, for example, heat treatment to decrease contact resistance, or die-bonding, wire-bonding, resin sealing, and the like entail heat stress and/or external stress. In addition, various types of stresses may be applied to the device after the manufacturing process. For instance, a device sealing process or a process of bonding the device to a circuit board may include application of heat stress thereto. The sealing process may also entail mechanical stress caused by sealing resin. Furthermore, heat or strain force may cause various stresses during use of a semiconductor device. For example, a semiconductor light emitting device used in an automobile may be subjected to various kinds of stresses including, heat and/or strain force, wherein such stresses are generated by car temperature, engine temperature, heat-shock due to diurnal and/or seasonal variation in temperature, exposure to solar UV radiation, car corrosion caused by water content and/or ambient gas (such as sulfate, chlorine, ozone), and so forth. Accordingly, it is very important to fabricate an electrode with excellent peeling-resistance capability independent of various stresses, thus ensuring high device performance, production yield and reliability.

Since ZnO-based compounds are wide band-gap semiconductors, metal materials having excellent ohmic characteristics which can be used as p-electrodes are limited. Therefore, there is still a strong demand for a metal electrode with high adhesion as well as excellent low-resistance ohmic-contact properties in order to provide manufacturing of improved ZnO-based semiconductor devices.

### SUMMARY OF THE INVENTION

However, with respect to ZnO-based compound semiconductor crystals, considerable research and investigation into fabrication of a contact electrode having excellent ohmic contact and excellent adhesion properties has not been conducted.

The present invention is directed to provide a method for forming a contact electrode having excellent ohmic contact properties as well as excellent adhesion properties without causing peeling of an electrode of a p-type ZnO-based compound semiconductor, a ZnO-based compound semiconductor device having the contact electrode described above, and a process for manufacturing the semiconductor device. The present invention also provides a ZnO-based compound semiconductor device with high performance, production yield and/or reliability while maintaining high adhesion, and device performances, independent of various stresses caused by stress due to heat or strain during manufacturing processes or environments of using the device and, in addition, a process for manufacturing the same.

According to the present invention, there is provided a method of manufacturing a zinc oxide based (ZnO-based) semiconductor device having at least p-type ZnO-based semiconductor layer, the method includes a first metal layer formation step of forming a first metal layer on the p-type ZnO-based semiconductor layer in island-form and/or mesh-form wherein the first metal layer contains at least one of nickel (Ni) and copper (Cu); a heat treatment step of performing heat treatment of the first metal layer and the p-type ZnO-based semiconductor layer under an oxygen-free atmosphere to form a mixture layer comprising elements of the p-type ZnO-based semiconductor layer and the first metal layer at a boundary region between the p-type ZnO-based semiconductor layer and the first metal layer while maintaining a metal phase layer on a surface of the first metal layer; and a second metal layer formation step of forming a second metal layer so as to cover the first metal layer and the exposed portions of the p-type ZnO-based semiconductor layer through openings of the first metal layer, the second metal layer comprising at least one of Pt (platinum), Rh (rhodium), Pd (palladium) and Ir (iridium).

According to the present invention, there is provided a ZnO-based semiconductor device having at least p-type ZnO-based semiconductor layer, the device includes a first metal layer formed on the p-type ZnO-based semiconductor layer in island-form and/or mesh-form wherein the first metal layer contains at least one of nickel (Ni) and copper (Cu); and a second metal layer formed so as to cover the first metal layer and the exposed portions of the p-type ZnO-based semiconductor layer through openings of the first metal layer, the second metal layer comprising at least one of Pt (platinum), Rh (rhodium), Pd (palladium) and Ir (iridium); wherein the first metal layer includes a mixture layer comprising elements of the p-type ZnO-based semiconductor layer and the first metal layer, the mixture layer being formed between the boundary of the p-type ZnO-based semiconductor layer and the first metal layer; and a metal phase layer formed on the surface of the first metal layer.

According to the present invention, there is provided a method for forming a contact electrode for a p-type ZnO-based semiconductor, the method includes a first metal layer formation step of forming a first metal layer on the p-type ZnO-based semiconductor layer in island-form and/or mesh-form wherein the first metal layer contains at least one of nickel (Ni) and copper (Cu); a heat treatment step of performing heat treatment of the first metal layer and the p-type ZnO-based semiconductor layer under an oxygen-free atmosphere to form a mixture layer comprising elements of the p-type ZnO-based semiconductor layer and the first metal layer at a boundary region between the p-type ZnO-based semiconductor layer and the first metal layer while maintaining a metal phase layer on a surface of the first metal layer; and a second metal layer formation step of forming a second metal layer so as to cover the first metal layer and the exposed portions of the p-type ZnO-based semiconductor layer through openings of the first metal layer, the second metal layer comprising at least one of Pt (platinum), Rh (rhodium), Pd (palladium) and Ir (iridium).

The first metal layer described above may have an average layer thickness in the range 3 nm to 15 nm.

The oxygen-free atmosphere described above may be any one of vacuum, an inert gas atmosphere, a reductive gas atmosphere and a mixture of an inert gas and a reductive gas.

The heat treatment described above may be conducted at a temperature in the range of 350 to 450° C.

### BRIEF DESCRIPTION OF THE DRAWINGS

FIG. 1 is a flow chart illustrating a sequential order of a process for manufacturing a semiconductor device according to the present invention;

FIG. 2 is a cross-sectional view showing an LED device-layer-formed substrate fabricated by depositing a ZnO-based compound semiconductor layer on a ZnO substrate;

FIGS. 3A to 3D are cross-sectional views schematically showing a process of fabricating an LED device;

FIGS. 4A to 4C are cross-sectional views schematically showing a detailed process of forming a p-side electrode.

FIGS. 5A and 5B are a top view and a cross-sectional view taken along the line A-A of the top view, showing a fabricated LED device;

FIG. 6 illustrates evaluation results of threshold voltage of V-I characteristics and peeling of a p-electrode of an LED according to a first embodiment of the present invention, compared to those of LEDs fabricated in Comparative Examples 1 and 2;

FIGS. 7A to 7C are schematic enlarged views of the contact portion, which illustrate effects of heat treatment conducted where electrode metal of a first p-electrode layer is formed on a ZnO-based crystal layer;

FIG. 8 is a partially enlarged view showing, in detail, a mixture region formed at a boundary between a ZnO-based crystal layer and a first p-electrode layer;

FIG. 9 is an enlarged cross-sectional view showing a contact portion of a p-electrode around a boundary region W (FIG. 3C) between a ZnO-based crystal layer and a first p-electrode layer;

FIGS. 10A and 10B are a top view and a cross-sectional view taken along the line A-A in the top view, showing an LED device according to a second embodiment of the present invention;

FIG. 11 is an enlarged cross-sectional view schematically showing a configuration of a p-electrode in the LED device fabricated according to the second embodiment;

FIGS. 12A and 12B are a top view and a cross-sectional view taken along the line A-A in the top view, showing an LED device according to a third embodiment of the present invention; and

FIG. 13 is an enlarged cross-sectional view schematically showing a configuration of a p-electrode in the LED device according to the third embodiment.

### DETAILED DESCRIPTION OF THE INVENTION

Hereinafter, preferred embodiments of a process for forming a metal electrode on a semiconductor crystal laminate or layered structure which is formed by laminating or stacking crystal layers comprising a ZnO-based compound semiconductor on a ZnO substrate and, in addition, a process for manufacturing a semiconductor device having an electrode formed therein will be described in detail with reference to the accompanying drawings. The following description will be made for growing layers to complete the above-described semiconductor crystal layered structure (i.e., multi-layer structure) used for manufacturing an LED (Light Emitting Diode) device as an example.

### First Embodiment

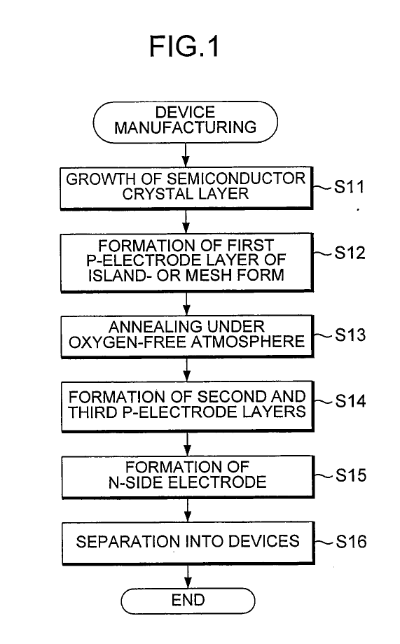

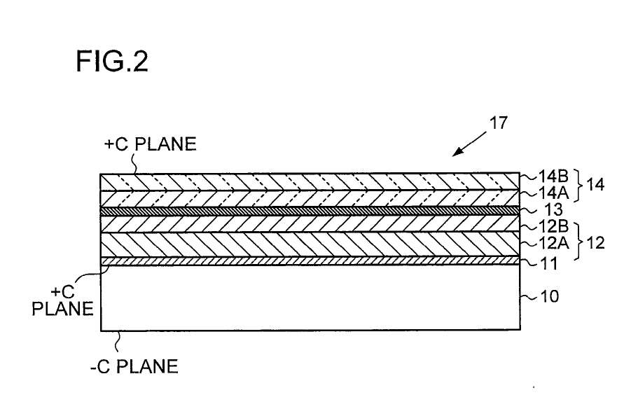

With reference to a flow chart shown in FIG. 1, a method of manufacturing an LED device according to the present invention is described in detail. FIG. 2 is a cross-sectional view showing an LED device-layer-formed substrate 17 fabricated by growing a ZnO-based compound semiconductor layer on a ZnO substrate 10.

Using a radical source-molecular beam epitaxy (RS-MBE) apparatus, ZnO-based compound semiconductor crystal layers were sequentially formed on a substrate 10 (FIG. 1, Step S11). In the RS-MBE, metal materials, that is, zinc (Zn), magnesium (Mg) and gallium (Ga) were evaporated or effused and provided over the substrate 10 using a Knudsen cell. As a gas source, oxygen O and nitrogen N were supplied in oxygen radical (represented by O*) and nitrogen radical (represented by N*). The substrate 10 was heated using an electric resistance heater.

The substrate 10 comprises ZnO single crystal having a {0001} plane of a Wurtzite structure as a main surface, and having a thickness of 500 μm, for example. More particularly, ZnO-based crystal layers were grown on a substrate 10 having a Zn polar plane (+c plane) as a crystal growth plane.

As shown in FIG. 2, a buffer layer 11 which is a ZnO layer having a thickness of 30 nm was firstly grown on the +c plane of the ZnO substrate. Here, the buffer layer 11 was a low-temperature grown buffer layer and a growth temperature Tg was 300° C. After growing the buffer layer 11, heat treatment (annealing) was conducted at a temperature T of 900° C. for 5 minutes.

Following this, a first n-type ZnO-based crystal layer 12A and a second n-type ZnO-based crystal layer 12B were grown in this order on the buffer layer 11 at a growth temperature Tg of 900° C. The first n-type ZnO-based crystal layer 12A was a ZnO layer having a thickness of 300 nm and a gallium (Ga) concentration of 3×10¹⁸ cm⁻³, while the second n-type ZnO-based crystal layer 12B was an Mg_{0.2}Zn_{0.8}O layer having a thickness of 50 nm and a Ga concentration of 3×10¹⁸ cm⁻³.

On the second n-type ZnO-based crystal layer 12B, a light emitting layer 13 was grown at a growth temperature Tg of 900° C. The light emitting layer 13 was an undoped ZnO layer having a thickness of 30 nm.

Next, a first p-type ZnO-based crystal layer 14A and a second p-type ZnO-based crystal layer 14B were grown in this order on the light emitting layer 13 at a growth temperature Tg of 700° C. The first p-type ZnO-based crystal layer 14A was an Mg_{0.2}Zn_{0.80} layer having a thickness of 30 nm and a nitrogen (N) concentration of 1×10²⁰ cm⁻³, while the second p-type ZnO-based crystal layer 14B was a ZnO layer having a thickness of 100 nm and a nitrogen concentration of 1×10²⁰ cm⁻³.

Based on the forgoing description, hereinafter, a layer comprising the first n-type ZnO-based crystal layer 12A and the second n-type ZnO crystal layer 12B is referred to as an n-type ZnO-based crystal layer 12 and a layer comprising the first p-type ZnO-based crystal layer 14A and the second p-type ZnO crystal layer 14B is referred to as a p-type ZnO-based crystal layer 14. A layered structure comprising the n-type ZnO-based crystal layer 12, the light emitting layer 13 and the p-type ZnO-based crystal layer 14 is also referred to as a device layer (LED layer) 15. Although the present embodiment describes the n-type ZnO-based crystal layer 12 and the p-type ZnO-based crystal layer 14, each of which comprises multiple crystal layers with different constitutional compositions and different thicknesses, each of the n-type ZnO-based crystal layer and the p-type ZnO-based crystal layer may be a single layer. As such, the device layer 15 (i.e., LED device layer) comprising the n-type ZnO-based crystal layer 12, the light emitting layer 13 and the p-type ZnO-based crystal layer 13 was formed (FIG. 1, Step S11).

The device layer herein means a layer (or multi-layer) formed of semiconductor required for a semiconductor device in order to accomplish desired performance thereof. For example, a simple transistor may have a structural layer comprising an n-type semiconductor, a p-type semiconductor and another n-type semiconductor (or, a p-type semiconductor, an n-type semiconductor and another p-type semiconductor) having pn junctions.

A semiconductor structural layer comprising a p-type semiconductor layer, a light emitting layer and an n-type semiconductor layer (or, a p-type semiconductor layer and an n-type semiconductor layer), wherein light emitting behavior of the structural layer is embodied by recombination of carriers injected thereinto, is especially called ‘light emitting device layer.’ In addition, for an LED, the foregoing semiconductor layer may be referred to as an ‘LED device layer.’

A crystal growing process is not limited to RS-MBE. That is, other crystal growing methods such as metal organic chemical vapor deposition (MOCVD), pulse laser deposition (PLD), etc. may also be used.

Configurations of the buffer layer 11, the n-type ZnO-based crystal layer 12, the light emitting layer 13 and the p-type ZnO-based crystal layer 14, or configurations of the first n-type ZnO-based crystal layer 12A and the second n-type ZnO-based crystal layer 12B, and the first p-type ZnO-based crystal layer 14A and the second p-type ZnO-based crystal layer 14B, that is, crystal composition, thickness, dopant concentration, etc. of each of the foregoing layers may be suitably defined or modified according to a device structure. For example, the buffer layer 11 may be an n-type MgₓZn₍₁₋ₓ₎O layer (wherein 0≦x<0.43) comprising a ZnO-based crystal containing Mg. The buffer layer 11 may be, for example, an n-type MgₓZn₍₁₋ₓ₎O layer (wherein 0≦x<0.43) that is several nonometers (nm) to several micrometers (μm) thick and is doped with impurities (e.g., Ga). Additionally, the n-type ZnO-based crystal layer 12 may be an n-type MgₓZn₁₋ₓ₎O layer (0≦x<0.43) that has a thickness of several tens of nanometers to several micrometers and is doped with impurities (e.g., Ga) at a doping concentration of 1×10¹⁷ cm⁻³ to 5×10¹⁸ cm⁻³. On the other hand, the light emitting layer 14B may include a configuration of a single quantum well (SQW) structure that consists of a quantum well and a barrier layer each having a thickness of several nanometers, for example, a multiple quantum well (MQW) structure having multiple quantum wells and barrier layers, or an MgₓZn₍₁₋ₓ₎O layer (wherein 0≦x<0.43) with a single constitutional composition.

The p-type ZnO-based crystal layer 14 may be a p-type MgₓZn₍₁₋ₓ₎O layer (wherein 0≦x<0.43). For example, the p-type ZnO-based crystal layer 14 may be a p-type MgₓZn₍₁₋ₓ₎O layer (0≦x<0.43) that has a thickness of several tens of nanometers to several micrometers and is doped with nitrogen (N) at a doping concentration of 1×10²⁰ cm⁻³.

Constitutional compositions, thicknesses and dopant concentrations of the foregoing layers described above are for illustrative purposes and may be suitably selected and/or modified to achieve desired device characteristics.

### [Configuration and Formation of P-Side Electrode]

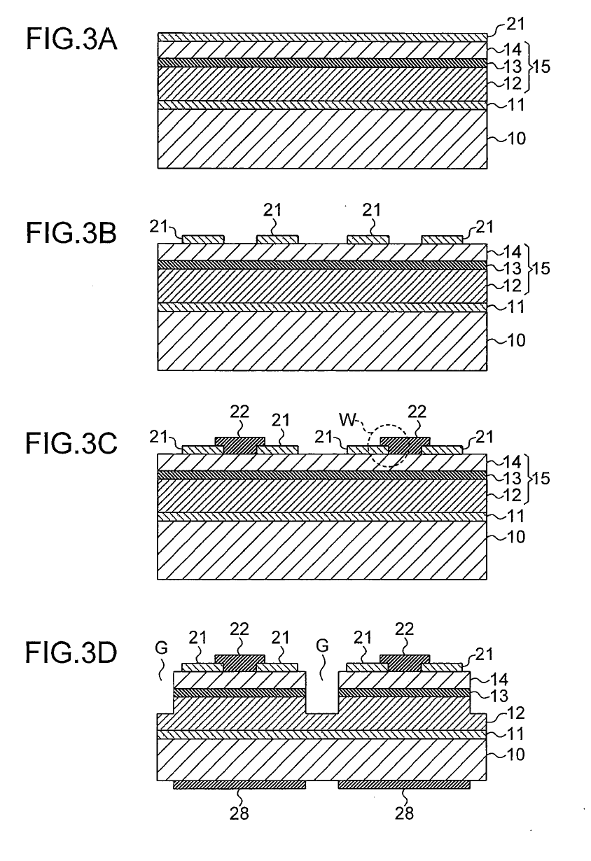

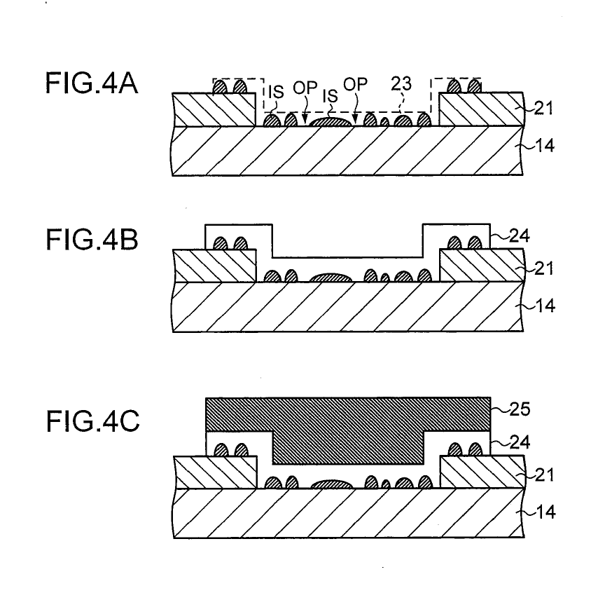

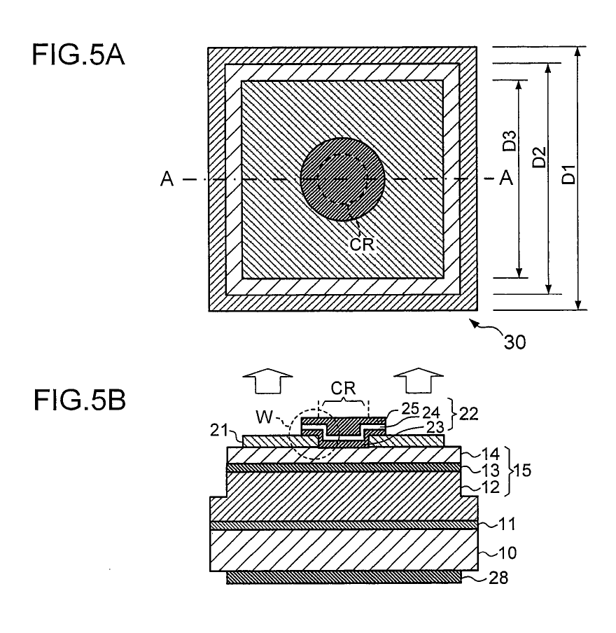

Hereinafter, a ZnO-based compound semiconductor device (LED) is fabricated using a substrate 17 having the LED device layer formed as described above (simply referred to as ‘device-layer-formed substrate’). FIGS. 3A to 3D are cross-sectional views schematically showing an LED device fabrication process. FIGS. 4A to 4C are cross-sectional views schematically showing a detailed process of forming a p-side electrode. FIGS. 5A and 5B are a top view and a cross-sectional view taken along the line A-A of the top view, showing a fabricated LED device;

First, a p-side electrode was formed on the p-type ZnO-based crystal layer 14 of the device-layer-formed substrate 17. More specifically, using photographic techniques, a resist mask having an opening in a form of a light transmissive conductive electrode (herein, referred to as transparent electrode) 21 (FIG. 5A, see the top view) was formed. In more detail, resist patterning was performed such that the transparent electrode 21 was formed in a rectangular shape with a circular contact region CR having a diameter of 100 μm in the center of the transparent electrode 21, thus allowing ohmic contact of a p-side electrode 22 (described below) and the p-type ZnO-based crystal layer 14. According to the embodiment of the present invention, the transparent electrode 21 was formed in a square shape having sides of 270 μm (D3), which is about 15 μm smaller than a size of a square device partition having sides of D2 (300 μm)(FIGS. 5A and 5B). In addition, the device was formed to have a square form having sides of 400 μm (D1), and a thickness thereof was 200 μm as described below.

Next, Ni (Nickel) and Au (gold) were deposited in sequential order to thicknesses of 5 nm and 30 nm, respectively, by EB (Electron Beam) deposition so as to form a Ni/Au layer (FIG. 3A). The Ni/Au layer means a laminate comprising a Ni layer as a first layer and a Au layer as a second layer and are hereinafter described with the same meaning. By lift-off processing, other portions of the Ni/Au layer except for a mask opening portion were removed (FIG. 3B).

Subsequently, the Ni/Au layer was subjected to transparent treatment at 450° C. for 30 seconds, using a rapid thermal annealing (RTA) apparatus. Nitrogen gas containing 20% oxygen was used for the transparent treatment. By performing this process, Ni in the Ni/Au layers is oxidized to produce nickel oxides (NiO, Ni₂O), thus making the electrode 21 transmissive (i.e., transparent or translucent).

Then, a p-side electrode 22 comprising three electrode layers (hereinafter, referred to as p-electrode layers) was formed (FIG. 3C). Hereinafter, the p-electrode layers refer to first, second and third p-electrode layers 23, 24 and 25, respectively, which are described in detail below.

Firstly, a metal mask having an opening to match a shape of the p-side electrode 22 (see FIG. 5A, a circular shape according to the present embodiment) was set in a metal mask cell. Then, the substrate was set such that the center of the transparent electrode 21 formed by the above-described process was in alignment with the center of an opening of the mask. Then, as schematically shown in FIG. 4A, Ni as the electrode metal of the first p-electrode layer 23 (i.e., contact electrode) was formed on the second p-electrode layer 24 to have a morphology or geometry of islands and/or mesh (hereinafter, referred to as island-form and/or mesh-form) (FIG. 1, Step S12). Specifically, the electrode or deposited metal of island-form and/or mesh-form, herein, referred to as electrode “layer” or metal “layer.”

The metal layer or the first p-electrode layer 23 was formed by evaporation method using an electric resistance heater which is capable of making deposited particles of relatively large size. Further, a reductive gas (H₂) was introduced in the evaporation chamber using an MFC (mass flow controller) to attain a slightly higher evaporation pressure (i.e., about 10 times of normal pressure or about 1×10⁴ Pa, Pa: Pascal) for increasing the size of the deposited particles. The island-form and/or mesh-form metal formed as described above had an average layer thickness of 10 nm and the particle sizes (i.e., island diameters) were in the range of Φ10 nm to Φ100 nm. Further, another deposition on a sapphire substrate was performed according to above-described method to form a deposition film. The resistance of the deposition film was measured to determine a non-conductive or high resistance conditions and the above-described deposition was performed using the determined conditions.

Then, the metal mask cell carrying the substrate was set in an RTA apparatus and an N₂ gas mixture containing 3% hydrogen gas was introduced into the apparatus. Under a reductive atmosphere, heat treatment (annealing) was conducted at 400° C. for 1 second (FIG. 1, Step S13). As such, the first p-electrode layer 23 was formed.

Following this, the metal mask cell was set in an EB apparatus. Platinum (Pt) as a barrier metal was deposited to thickness of 100 nm to form the second p-electrode layer 24. Gold (Au) as a connection electrode (or pad electrode) metal was deposited to thickness of 1000 nm on the second p-electrode layer 24 to form the third p-electrode layer 25 (FIGS. 4A and 4B, Step S14 of FIG. 1). As such, the p-side electrode 22 comprising the first, second, and third p-electrode layers 23, 24 and 25 was formed.

As described above, the electrode metal (Ni) was formed in island-form and/or mesh-form in the first p-electrode layer 23. Specifically, the island-form and/or mesh-form metal (Ni) layer was formed to have openings OP (FIG. 4A). Additionally, the first p-electrode layer 23 (Ni layer) of island-form and/or mesh-form was formed so as to be encompassed or embedded by the deposited second p-electrode layer 24. In other words, the entire surface of the first p-electrode layer 23 (Ni layer) was covered by the second p-electrode layer 24. The metal (Pt) of the second p-electrode layer 24 was directly in contact with the p-type ZnO-based crystal layer 14 at the portions or areas (i.e., openings OP) where the metal (Ni) of the first p-electrode layers 23 was not formed on the p-type ZnO-based crystal layer 14 to cover the p-type ZnO-based crystal layer 14. The second p-electrode layer 24 was formed to cover the portions of the p-type ZnO-based crystal layer 14 exposed through the openings OP of the first p-electrode layers 23 (i.e., exposed portions of the p-type ZnO-based crystal layer 14).

Using photolithography, a resist mask having an opening of a shape of the device partition (i.e., square with side lengths of D2, FIG. 5) was formed on a front side of the substrate having the p-side electrode 22 formed thereon. Performing wet etching, the n-type ZnO-based crystal layer 12 was etched to a depth to remove a portion thereof, so as to form a device partition groove G (FIG. 3D).

The device-layer-formed substrate 17 was bonded to a support body (hereinafter, simply referred to as support) such that the front side of the substrate having the p-side electrode 22 formed thereon was in contact with the support, and a back side of the device-layer-formed substrate 17 was subjected to mirror polishing to a thickness of about 200 μm. Subsequently, photolithography and EB deposition were conducted to deposit Ti and Au to thicknesses of 100 nm/1000 nm (Ti/Au=100 nm/1000 nm), respectively, to the back side of the device-layer-formed substrate 17, thereby forming an n-side electrode 28 with the same shape as of the device partition (Step S15 in FIG. 1, FIG. 3D). Further, as an ohmic electrode metal layer of the n-side electrode 28, TI/Rh/Au layers may be used. Thicknesses of the layers may be, for example: Ti/Rh/Au=3-30 nm/50-100 nm/500-1000 nm; or Ti/Rh/Au=10 nm/80 nm/1000 nm. Alternatively, Ti/Al/Au layers may be used as the n-side ohmic electrode metal layer. Thicknesses of the layers may be, for example: Ti/Al/Au=3-30 nm/50-100 nm/500-1000 nm; or Ti/Al/Au=10 nm/80 nm/1000 nm.

After completing formation of the n-side electrode 28, the device-layer-formed substrate 17 was subjected to scribing and breaking along the device partition groove G, so as to divide the substrate into separate LED devices (FIG. 1, Step S16). FIGS. 5A and 5B are a top view and a cross-sectional view showing an LED device fabricated as described above. Arrows in the figures indicate light emission direction.

### [Evaluation of Electrical and Adhesion Properties]

With respect to an LED device fabricated according to the first embodiment as described above, electrical properties and adhesion properties of the LED device were evaluated and compared to those of LED devices for comparison (hereinafter, also referred to as “Comparative Examples”) with the device of the invention. More particularly, for an LED according to the first embodiment and LEDs of Comparative Examples 1 and 2, ohmic characteristics based on threshold voltage of V-I characteristics were evaluated. Also, an adhesion strength of a p-side electrode was evaluated by monitoring whether the electrode peels off or not upon wire-bonding. Each of the LED devices of the first embodiment and the Comparative Examples 1 and 2 was subjected to heat treatment at 350° C. for 15 seconds under N₂ gas atmosphere, in consideration of heat history or cycle when mounting a device. After the heat treatment, the LED devices were evaluated according to the above-described procedures. For each of the first embodiment and Comparative Examples 1 and 2, 25 samples (i.e., LEDs) were selected and a total of 75 samples were evaluated.

### Comparative Example 1 and Comparative Example 2

With respect to LEDs of Comparative Example 1, Ni and Au were used as a first p-electrode layer and a second p-electrode layer, respectively. EB deposition was conducted to deposit a Ni/Au layer to thicknesses of 30 nm/1000 nm, thereby forming a p-side electrode. Then, annealing of the first and second p-electrode layers were not performed. Except for a configuration of the p-electrode and a process for forming the same, the same procedures as descried in the first embodiment were used. Specifically, configurations of a semiconductor crystal layer, a transparent electrode and an n-side electrode and other processes for fabrication of devices are substantially the same as described in the first embodiment.

With respect to an LED of Comparative Example 2, Ni was used as a first p-electrode layer. That is, Ni was formed to a thickness of 30 nm by EB deposition. After deposition, annealing was performed using an RTA apparatus at 450° C. for 1 minute under an N₂ atmosphere containing 20% O₂ gas (an oxygen atmosphere or an oxidative gas atmosphere). More particularly, according to the annealing process, nickel oxides (NiO+Ni₂O) were formed as the first p-electrode layer including a surface portion thereof.

After annealing, Au as a second p-electrode layer was deposited to a thickness of 1000 nm by EB deposition, thus completing formation of a p-side electrode. In this case, the same procedures as described in the first embodiment were used except for a configuration of the p-side electrode and a process for formation thereof.

### (Evaluation Results)

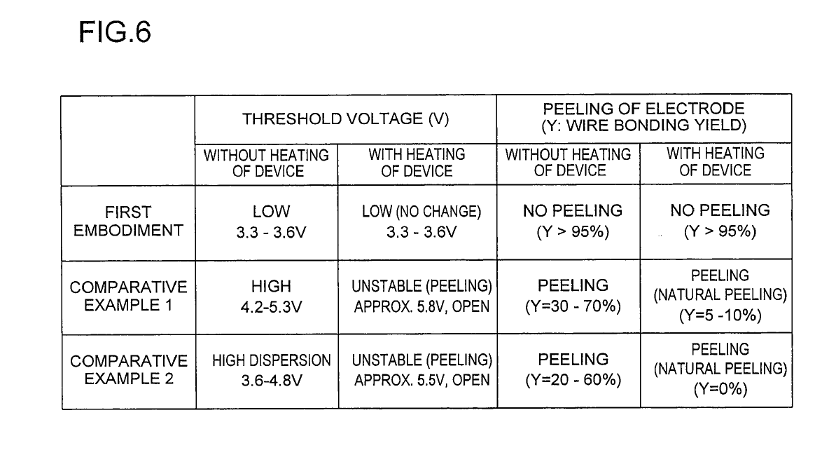

With respect to LEDs of the first embodiment and Comparative Examples 1 and 2, evaluation results of threshold voltages of V-I characteristics and peeling of a p-side electrode are summarized in FIG. 6. In consideration of heat history at the time of mounting a device after manufacture, for example, a heating process performed for device mounting such as a reflow soldering in die-bonding (at about a temperature of 230 to 270° C.) or Au/Sn bonding (at a temperature of 300 to 350° C.), the fabricated devices were subjected to heat treatment at 350° C. for 15 seconds. For the heat-treated devices, evaluation results of threshold voltage and electrode peeling are shown in the figure.

It can be seen that the LED of the first embodiment has excellent diode characteristics and ohmic contact properties, since the V-I curve of the LED shows a steep rising edge and a threshold voltage (VT) is low. Specifically, as shown in FIG. 6, the threshold voltages (VT) of the samples of the first embodiment are relatively low and in the range of 3.3 to 3.6V. It was found that the device shows stable characteristics without alteration thereof even after heating.

On the other hand, the threshold voltages of the samples of Comparative Example 1 were of high level of 4.2 to 5.3V and a statistical dispersion of the threshold voltages was also high. With regard to heat treatment of a device, there were quite a number of samples not evaluated due to electrode peeling (i.e., open state). Even for samples that could be evaluated, the threshold voltage VT was about 5.8V, which is considerably high. Like the samples of Comparative Example 1, samples of Comparative Example 2 also had a high VT of 3.6 to 4.8V and a high statistical dispersion of threshold voltages. After heat treatment of the devices, many samples could not be evaluated due to electrode peeling (i.e., in an open state).

For the purpose of evaluation of electrode adhesion properties, samples of the first embodiment, Comparative Example 1 and Comparative Example 2 were subjected to die-bonding to stems using an Ag paste, followed by Au wire-bonding. All of the samples of the first embodiment did not show electrode peeling and wire-bonding could be performed. Bonding failure was observed from some samples of the first embodiment, although such failure was caused by incorrect die-bonding position rather than problems in electrode adhesion. Wire-bonding was also suitably performed without problems even after heat treatment of the device.

For samples of Comparative Examples 1 and 2, electrode peeling occurred with considerable frequency during wire-bonding. Also, non-uniformity between sample lots was high and a wire-bonding yield was 60 to 70% for good samples and 20 to 30% for bad samples. After heat treatment, natural electrode peeling and electrode peeling during bonding were often observed and a wire-bonding yield was 5 to 10% at most.

Based on the above-described evaluation results, it was demonstrated that a configuration of an electrode and a process for manufacturing an electrode according to the first embodiment show excellent ohmic characteristics suitable for an electrode for ZnO-based semiconductor devices and have high adhesion properties and adhesion strength. In addition, it was found that the electrode according to the first embodiment maintains excellent characteristics during heat treatment after device manufacture, as well as excellent heat resistance.

### [Analysis of Improvement in Ohmic Characteristics and Adhesion Properties]

Improvement in ohmic characteristics and adhesion properties of a p-side electrode according to the embodiments was examined and analyzed. A mechanism of improvement in such characteristics or properties will be described in detail with reference to the accompanying drawings.

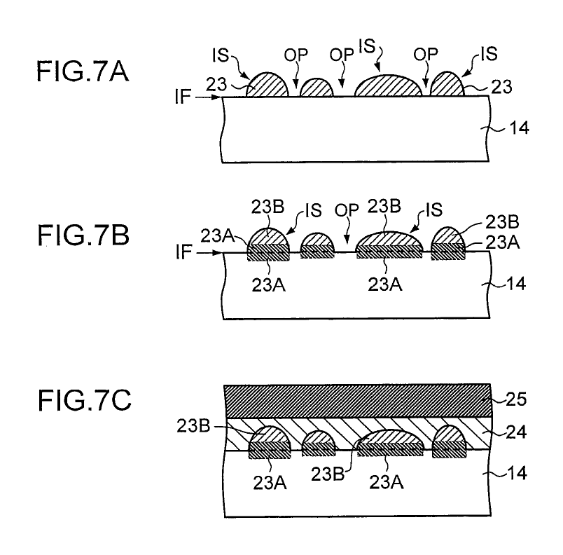

FIGS. 7A and 7B are enlarged views showing a p-type ZnO-based crystal layer 14 and a contact portion of an electrode metal in order to schematically illustrate effects of a process for forming the electrode metal (Ni) of a first p-electrode layer 23 deposited in island-form and/or mesh-form on the p-type ZnO-based crystal layer 14 and then heating (annealing) the layers. FIG. 7C is a cross-sectional view showing a process of forming a second p-electrode layer 24 and a third p-electrode layer 25 on the first p-electrode layer 23 after annealing.

According to the first embodiment as shown in FIG. 7A, in order to form the first p-electrode layer 23, Ni which is readily oxidized was used as the electrode metal and deposited in island-form and/or mesh-form on the p-type ZnO-based crystal layer 14 by vapor deposition. In other words, a contact electrode metal (Ni) of island-form and/or mesh-form is placed on and in contact with the p-type ZnO-based crystal layer 14 after deposition. As described above, the metal (Pt) of the second p-electrode layer 24 was directly in contact with the p-type ZnO-based crystal layer 14 in the openings OP of the metal layer of island-form and/or mesh-form.

In the following, description will be made for a case where the electrode metal (Ni) is of island-form, that is, where the first p-electrode layer 23 comprises islands IS of electrode metal (Ni) for brevity of the description and the ease of understandings. However, it should be understood in an analogous fashion for the cases where the islands IS are combined or connected to form the electrode metal (Ni) of mesh-form or where the electrode metal is formed as mixture of the islands and mesh-form metal.

In the first embodiment, annealing was conducted under a reductive atmosphere (or oxygen-free ambient) after Ni deposition. It is considered, as shown in FIG. 7B, that a region 23A (hereinafter, referred to as ‘mixture region MR’) at which atoms contained in the p-type ZnO-based crystal layer 14 and the Ni layer (the first p-electrode layer) were combined and/or mixed in various states was formed in the vicinity of the boundary IF between the p-type ZnO-based crystal layer 14 and the islands IS (Ni) of the first p-electrode layer 23 by the annealing process. In addition, a pure metal layer (Ni layer) 23B remains on the portion other than the mixture region 23A of the island IS, that is, a surface portion of the island IS.

In more detail, oxygen (O) is provided only from a ZnO-based crystal (i.e., p-type ZnO-based crystal layer 14) during annealing under a reductive atmosphere (or, oxygen-free atmosphere or non-oxidative atmosphere). Accordingly, atoms present at the boundary are inter-diffused by annealing. The layer of readily oxidized metal (Ni) changes in the interior thereof continuously from a metal phase layer to an oxide phase layer, in accordance with an amount of oxygen diffused thereinto through the boundary. That is, an amphoteric layer capable of forming a metallic bond to metal and a covalent bond to oxide is formed. More particularly, oxygen atoms contained in the ZnO-based crystal move into Ni deposited on the crystal while movement of Ni atoms into the ZnO-based crystal is promoted. As a result, Zn, Ni and O are mixed and combined in various states to form the mixture region (or mixture layer) 23A at the boundary (IF) region between the p-type ZnO-based crystal layer 14 and the islands IS.

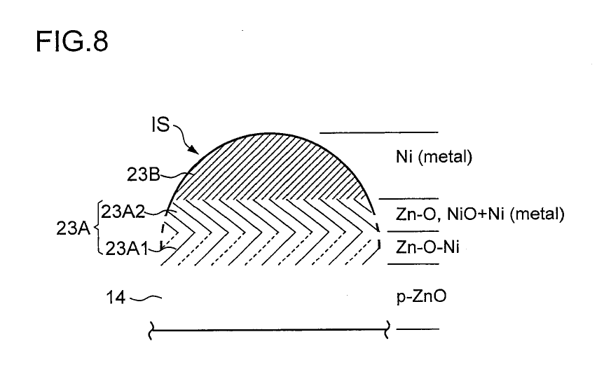

FIG. 8 is a partially enlarged cross-sectional view schematically illustrating the boundary region between the p-type ZnO-based crystal layer 14 and the islands IS (the first p-electrode layer 23). The following description will be given to explain, in detail, the mixture region 23A described above. Referring to FIG. 8, it is considered that the mixture region 23A has a configuration including: a mixture region 23A1 comprising a mixed crystal phase (Zn—O—Ni) layer of ZnO and NiO; and another mixture region 23A2 comprising a layer of ZnO, and NiO phase and Ni metal phase (NiO, Ni₂O+Ni metal). A thickness of the mixture region 23A may range from several to less than twenty monolayers (i.e., atomic layers), in consideration of the average layer thickness and the island diameter of the deposited Ni layer. The regions are not clearly partitioned from one another, although they may have different states and/or thicknesses based on annealing conditions such as temperature.

Further, in another aspect of the present invention, the above-described boundary oxidation process does not show alteration in number of atoms contained in the boundary region and also has little variation in volume. Accordingly, internal distortion of the mixture region is small. Furthermore, since the deposited metal (Ni) layer has an island-form and/or mesh-form, there is only a little variation in volume and stress, thus peeling can more effectively be avoided as compared with a case where a metal (Ni) layer has no opening to cover the entire surface of the p-type ZnO-based crystal layer 14. Further, since the mixture region includes a relatively hard oxide portion and a relatively soft metal portion, for example, stress caused by variation in volume may be absorbed even when the volume is varied.

As described above, under desired annealing conditions in the embodiment of the present invention, O₂ contained in ambient gas or ZnO crystal does not move or is not provided onto a surface of the deposited layer of island-form and/or mesh-form and a single layer with a metal phase comprising a pure metal (Ni) (that is, Ni metal layer) 23B remains on the surface of the Ni layer of island-form and/or mesh-form.

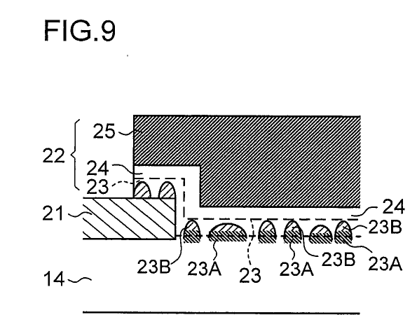

FIG. 9 is an enlarged cross-sectional view illustrating a contact portion of the p-side electrode 22 at the boundary portion W between the transparent electrode 21 and the p-side electrode 22 (FIG. 3C and FIG. 5B). The mixture region 23A is formed at a boundary portion between the p-type ZnO-based crystal layer 14 and the first p-electrode layer 23 (i.e., islands IS), while the metal layer (Ni layer) 23B remains on the surface of the island IS of the first p-electrode layer 23. On the first p-electrode layer (Ni layer) 23B, the second p-electrode layer 24 as a barrier metal (i.e., Pt) and the third p-electrode layer 25 as a pad metal are formed.

According to the present invention, the p-side electrode 22 having excellent adhesion properties and adhesion strength can be provided for the following reasons.

The deposited layer has excellent adhesion properties and adhesion strength with the second p-electrode layer 24 as a barrier metal, since the metal phase layer 23B remains on the surface portion of the deposited layer. Further, the mixture region 23A is formed at the boundary portion between the p-type ZnO-based crystal layer 14 and the first p-electrode layer 23, thus excellent adhesion properties and adhesion strength can be obtained between the p-type ZnO-based crystal layer 14 and the first p-electrode layer 23. In other words, the first p-electrode layer 23 has a two-phase configuration with superior adhesion to both oxide and metal, wherein the layer 23 adheres to the p-type ZnO-based crystal layer 14 as an oxide crystal and adheres to the second p-electrode layer 24 as metal.

In addition, excellent adhesion can be obtained between the p-type ZnO-based crystal layer 14 and the second p-electrode layer 24 via the first p-electrode layer 23. More specifically, the second p-electrode layer 24 (barrier metal) is in contact with the p-type ZnO-based crystal layer 14 in the openings OP of the first p-electrode layer 23 (Ni layer). Accordingly, peeling stress can be dispersed as compared with a case where the barrier metal is formed on the entire surface of the p-type ZnO-based crystal layer 14. In other words, concentration of peeling stress is likely to occur when the second p-electrode layer 24 (barrier metal) is formed on the entire surface of the p-type ZnO-based crystal layer 14. On the other hand, since the first p-electrode layer 23 is formed to have an island-form and/or mesh-form, stress can be dispersed and peeling hardly occurs. Additionally, even if a small peeling occurs at a portion of the second p-electrode layer 24, development of the peeling can be avoided. This can be explained as follows. Peeling of the second p-electrode layer 24 from the p-type ZnO-based crystal layer 14 at the opening OP propagates in the transverse direction on the surface of the p-type ZnO-based crystal layer 14 form the peeling occurrence point. The first p-electrode layer 23 (islands IS) of island-form and/or mesh-form prevents the peeling propagation.

Specifically, the area coverage of the first p-electrode layer 23 on the p-type ZnO-based crystal layer 14 is preferably in the 20% to 80% range. Peeling of the electrode is likely to occur because of poor adhesion strength of the electrode when the coverage is less than 20%. Additionally, peeling of the electrode is likely to occur when the coverage exceeds 80%, because adhesion strength is degraded by oxidation of the first p-electrode layer 23 due to a heat application process after fabrication of the electrode. The area coverage is more preferably in the 30% to 70% range.

From the viewpoint of the contact resistance, the area coverage is preferably in the 30% to 60% range. The contact resistance of the first p-electrode layer 23 varies to some extent according to the heat treatment under reductive atmosphere, whereas the contact resistance of the second p-electrode layer 24 is stable. Therefore, the area of the second p-electrode layer 24 is preferably larger to the extent necessary for avoiding deterioration in the adhesion strength.

According to the present invention, the p-side electrode having not only adhesion properties but also excellent ohmic characteristics can be provided as follows.

The mixture region is formed at the boundary between the p-type ZnO-based crystal layer 14 and the first p-electrode layer 23 thus presenting excellent ohmic characteristics at the boundary. Further, excellent ohmic characteristics can be provided in the openings of the first p-electrode layer 23, since barrier metal (Pt) which shows excellent ohmic characteristics to the p-type ZnO-based crystal layer 14 is used as the second p-electrode layer 24. Accordingly, the p-side electrode 22 provides excellent ohmic characteristics due to the ohmic contact between the p-type ZnO-based crystal layer 14 and the first p-electrode layer 23 and the ohmic contact between the p-type ZnO-based crystal layer 14 and the second p-electrode layer 24 (barrier metal) at the openings of the first p-electrode layer 23.

Further, according to the present invention, the first p-electrode layer 23 is formed so as to be embedded in the second p-electrode layer 24. In other words, the first p-electrode layer 23 of island-form and/or mesh-form is formed so as to cover the entire surface of the first p-electrode layer 23 of island-form and/or mesh-form and to cover the p-type ZnO-based crystal layer 14 in the openings of the first p-electrode layer 23. Accordingly, the total contact area of the second p-electrode layer 24 with the first p-electrode layer 23 and the p-type ZnO-based crystal layer 14 is larger than the formation area (i.e., two-dimensional area) of the A-side electrode 22. With this configuration, the p-side electrode 22 has excellent adhesion properties and adhesion strength and low contact resistance.

### [Conditions for Formation of the P-Side Electrode]

### (Material of the First P-Electrode Layer)

It is required that a metal having capable of forming an ohmic contact with a p-type ZnO-based crystal layer should be used for the first p-electrode layer 23. According to the present invention, it is required to provide an ohmic contact between the p-type ZnO-based crystal layer and electrode metal oxide, since the metal oxide is formed between the first p-electrode layer and the p-type ZnO-based crystal layer. NiO is known as such a p-type oxide crystal. However, an oxide of the other 3d transition metal element, for example, Cu oxide including Al (aluminum), Ca (calcium), or Sr (strontium), etc. can be formed into such p-type oxide crystals. Accordingly, the first p-electrode layer may be formed using Ni or Cu, or any one alloy consisting of Ni or Cu and Al, Ca or Sr. That is, metal or metal alloys containing at least one of Ni and Cu may be used for a contact metal described above.

### (Thickness of the First P-Electrode Layer)

The first p-electrode layer is formed to have island-form and/or mesh-form. More specifically, the first p-electrode layer should be formed to have island-form and to have an average layer thickness in the range 3 nm-15 nm and the island diameters in the range 410 nm to (0100 nm, and/or to be a mesh-form metal layer in which the islands are combined or connected.

The electrode layer (the first p-electrode layer) as-deposited does not include a mixture region and an oxide crystal layer and a metal layer are merely in contact with each other. Accordingly, if a deposition layer is too thick, the deposited electrode layer is likely to be peeled off. A thickness of the first p-electrode layer is preferably 10 nm or less.

### (Ambient Gas for Annealing of the First P-Electrode Layer)

The present invention adopts bonding ability of readily oxidized metals (Ni, Cu, or compounds of Ni or Cu and Al, Ca or Sr) with oxygen of a constitutional element of the p-type ZnO-based crystal layer and utilizes an ambient gas for heat treatment in order to oxidize only a boundary region between the p-type ZnO-based crystal layer 14 and the first p-electrode layer 23 using oxygen provided by the p-type ZnO-based crystal layer 14, while a metal phase layer remains on a top layer of the first p-electrode layer. The heat treatment, that is, annealing is preferably conducted under an oxygen-free atmosphere or non-oxidative atmosphere. Also, a reductive gas such as hydrogen (H₂) may be added to the atmosphere, enabling maintenance of the top layer of the first p-electrode layer 23 in a preferable metal state.

The ambient gas for annealing the first p-electrode layer 23 used in the first embodiment was an N₂ gas mixture prepared by adding 3% H₂ gas as a reductive gas to N₂ gas as an inert gas. Using a reductive atmosphere containing a small amount of H₂ gas (>0%), a surface of the first p-electrode layer 23 is maintained in a metal state and adhesion of the p-electrode layer 23 is improved. If H₂ content exceeds 10%, an amount of O₂ discharged from the surface of the ZnO-based crystal layer is increased and a surface absorption layer is likely to be formed, thus being not preferable. Therefore, the H₂ gas content preferably ranges from 0.05 to 10% and, more preferably, from 0.05 to 3%.

Alternatively, instead of N₂ gas, other inert gases such as helium (He), argon (Ar), etc. may be used. Also, as the reductive gas, H₂ may be replaceable with hydrazine (N₂H₄) or the like. However, when using the reductive gas, a heat treatment temperature should be decreased, so as to prevent the p-type ZnO-based crystal layer from being modified or deteriorated. Heat treatment may be conducted under vacuum, however, a container used for heat treatment must be sufficiently dehydrated to remove water content from an inner wall of the container.

Conditions for formation of the first p-electrode layer 23 depend on metal used, constitutional elements of the p-type ZnO-based crystal layer 14 and composition thereof, and annealing temperature and time. Therefore, according to examinations and/or evaluations, a useful gas and conditions for formation of the electrode layer are preferably selected.

### (Annealing Temperature)

If an annealing is performed at a low temperature of less than 350° C., it is difficult to form a mixed crystal layer (mixture region). On the other hand, it is not preferable to perform annealing at a high temperature of more than 500° C., since metal elements (Ni) of the first p-electrode layer 23 form a solid solution (or solid-state solution) in the ZnO-based crystal layer 14 such that mixed crystals formation extends to a surface layer of the electrode layer. Accordingly, the annealing temperature desirably ranges from 350 to 500° C. In order to prevent formation of a solid solution in a heating process in association with device mounting after manufacture, the annealing temperature more preferably ranges from 350 to 450° C.

### (Material of the Second P-Electrode Layer)

As described above, the metal of the second p-electrode layer 24 must be a one not to form a solid solution with the metal (Ni etc.) of the first p-electrode layer 23. Even at low temperature (i.e., less than several hundreds degree C.), metals may form a solid solution. Especially, since the average layer thickness of the first p-electrode layer 23 is thin in the range 3 nm-15 nm, the mixture region is lost due to formation of a solid solution and the adhesion strength is decreased to result in electrode peeling. Additionally, the metal of the second p-electrode layer 24 is preferably a one not to form a solid solution with the third p-electrode layer 25 even when providing the third p-electrode layer 25 such as a connection electrode (or pad electrode) on the second p-electrode layer 24.

Further, a material which provides an ohmic contact with the p-type ZnO-based crystal layer 14 should be used as the second p-electrode layer 24.

Accordingly, group-VIII transition metal which provides an ohmic contact with the p-type ZnO-based crystal, particularly, platinum (Pt), rhodium (Rh), palladium (Pd), iridium (Ir) etc. can be used.

The semiconductor device is subject to various heat history or cycle after fabrication, for example, when mounting a device on the board. As described above, electrode peeling can be prevented due to reduction of adhesion strength caused by loss of the mixture region by oxidation of the first p-electrode layer 23, using the metals such as Pt, Rh, Pd or Ir, and the configuration in which the first p-electrode layer 23 is embedded in its entirety.

Specifically, the second p-electrode layer 25 (barrier layer) may have a multi-layered structure. For instance, it is possible to combine a metal insoluble in the first p-electrode layer 23 with another metal insoluble in the third p-electrode layer 25. The metal used for the barrier layer is generally selected from metals with high hardness. For a thick barrier layer, distortion occurs due to a difference in thermal expansion coefficients of the barrier layer and the p-type ZnO-based crystal layer when heating so that electrode peeling may develop. This problem can be prevented by forming the second p-electrode layer with a specific structure wherein a plurality of barrier layers is piled to form a laminate and a soft metal (such as Au) is interposed therebetween.

### (Material of the Third P-Electrode Layer)

A material used for the third p-electrode layer 25 may be aluminum (Al) instead of Au. In general, Au is most preferably used as a bonding pad layer material, since Au is generally used as a bonding wire. On the other hand, Al is a highly reflective material that reflects even near-ultraviolet light and is thus suitable for suppressing light absorption by an electrode.

### (Timing of Annealing Process)

According to the first embodiment of the present invention, an annealing process to form a mixture region was performed after forming the first p-electrode layer 23. Such annealing may be performed after formation of the second p-electrode layer 24 (barrier layer) or the third p-electrode layer 25 (pad electrode layer).

However, the bonding state of crystal is varied according to movement (diffusion) of oxygen atoms during formation of the mixture region, causing significant spatial distortion. Accordingly, where the annealing is performed after formation of the first p-electrode layer 23, deterioration in adhesion and/or bonding strength of the mixture region is not caused since the metal layer is thin and spatial distortion is easily relaxed. Therefore, the annealing process performed after deposition of the first p-electrode layer 23 is most effective, compared to where the annealing process is performed after formation of the second p-electrode layer 24 or the third p-electrode layer 25.

### Second Embodiment

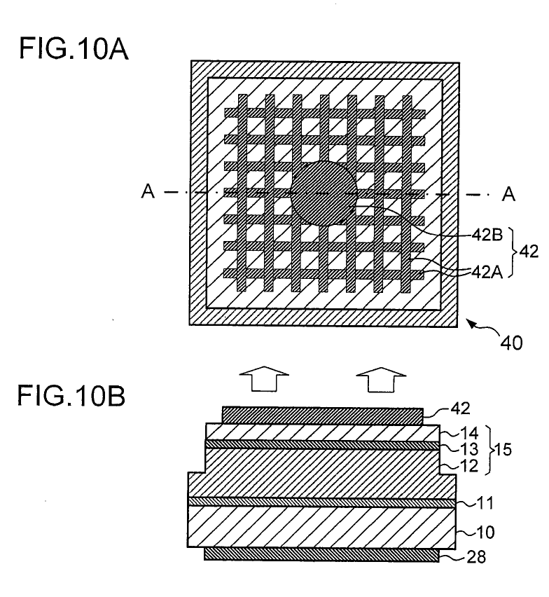

FIGS. 10A and 10B are a top view and a cross-sectional view taken along the line A-A of the top view, respectively, showing an LED device 40 fabricated according to a second embodiment of the present invention.

The configuration of the LED device 40 according to the second embodiment (Second Embodiment) is substantially the same as the LED device 30 of the first embodiment of the present invention, in terms of configurations, except that a mesh shape electrode structure is adopted. That is, a buffer layer 11, an n-type ZnO-based crystal layer 12, a light emitting layer 13 and a p-type ZnO-based crystal layer 14 were arranged on a ZnO substrate 10, so as to form a device layer 15.

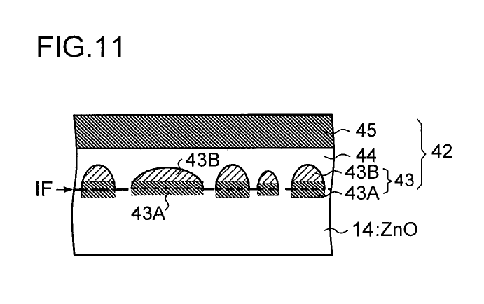

Using a device-layer-formed substrate formed as described above, the p-side electrode 42 was formed on the p-type ZnO-based crystal layer 14. The p-side electrode 42 includes a mesh-shape p-side electrode 42A and a circular-shape p-side electrode 42B (with a diameter of 100 μm) for wire bonding, which was placed in the center of a device. As shown in FIG. 11, the p-side electrode 42 includes first, second and third p-electrode layers 43, 44 and 45.

Hereinafter, a forming process of a p-side electrode 42 is described in detail below. Using photolithographic techniques, a resist mask having an opening corresponding to a mesh-shape p-side electrode 42A and a circular p-side electrode 42B was formed on a p-type ZnO-based crystal layer 14. Then, the first p-electrode layer 23 was formed in island-form and/or mesh-form. Specifically, Ni was deposited to an average thickness of 10 nm in island-form. The diameters of the islands were in the range (Φ10 nm to Φ100 nm. Subsequently, the Ni portion except for the mask opening was removed by a lift-off method.

Next, a substrate was set in an RTA apparatus and N₂ gas containing 3% H₂ gas as an ambient gas was supplied to the apparatus in order to conduct annealing at 400° C. for 10 seconds under a reductive atmosphere. As a result, a first p-electrode 43 was formed. More particularly, as shown in FIG. 11, the first p-electrode layer 43 was formed according to the same procedures described in the first embodiment wherein a mixture region MR 43A was formed by annealing at a boundary between the p-type ZnO-based crystal layer 14 and the deposited Ni islands, while a pure metal layer (Ni layer) 43B remains on each surface of the islands.

Then, using EB deposition, Pt (barrier metal) and Au were deposited to thicknesses of 100 nm and 1000 nm, respectively, so as to form a second p-electrode layer 44 and a third p-electrode layer 45.

After formation of the p-side electrode 42, a back side of the device-layer-formed substrate 17 was polished and an n-side electrode 28 was formed. The device-layer-formed substrate 17, after formation of the n-side electrode 28, was divided into separate LED devices by scribing and breaking.

As described in the first embodiment of the present invention, the mixture region is formed at the boundary between the p-type ZnO-based crystal layer 14 and the p-side electrode 42 and a metal phase layer (Ni layer) remains on a surface of the first p-electrode layer 43, so that excellent ohmic characteristics, high electrode adhesion properties and bonding strength can be achieved. Further, the second p-electrode layer 24 (i.e., barrier metal such as Pt) is directly in contact with the p-type ZnO-based crystal layer 14 at the opening portion, so that the p-side electrode 42 having excellent ohmic characteristics and high adhesion properties can be provided.

According to the second embodiment of the present invention, an electrode with improved low resistance ohmic characteristics can be provided since the mesh-shape p-side electrode 42 is formed over a light emitting plane. Since current injected from the p-side electrode 42B is diffused throughout a light emitting layer 13, a light emitting device having uniform current injection and high efficiency can be provided. In addition, electrode adhesion properties and bonding strength can be improved. A width of each line of the mesh electrode may be desirably defined in consideration of (external) light emission efficiency, contact resistance, electrode adhesion strength, etc.

### Third Embodiment

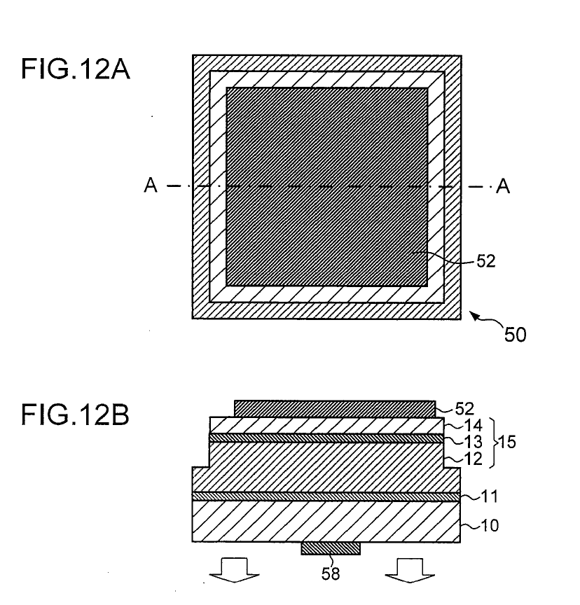

FIGS. 12A and 12B are a top view and a cross-sectional view taken along the line A-A of the top view, respectively, showing an LED device fabricated according to a third embodiment of the present invention.

An LED device 50 according to the third embodiment (Third Embodiment) has substantially the same configuration as the LED device 30 fabricated in the first embodiment, except that a flip-chip structure using an n-side electrode side as a light emitting plane and a light reflection structure are adopted. That is, a device layer 15 comprising a buffer layer 11, an n-type ZnO-based crystal layer 12, a light emitting layer 13 and a p-type ZnO-based crystal 14 was formed on a ZnO substrate 10.

The device-layer-formed substrate was used and a p-side electrode 52 was formed on the p-type ZnO-based crystal layer 14. A device partition size is identical to that described in the first embodiment (see FIG. 3) and, as shown in FIG. 12, the p-side electrode 52 was formed in a square shape having sides of 270 μm (D3), which is about 15 μm smaller than a size of a square device partition having sides of D2 (300 μm).

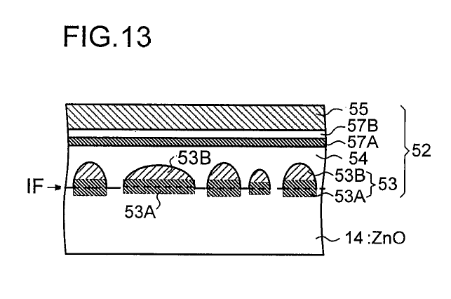

FIG. 13 is a cross-sectional view showing a configuration of the p-electrode 52. The p-side electrode 52 has a configuration including: first, second and third p-electrode layers 53, 54 and 55; and a reflection layer 57A and a reflection-protecting layer 57B which are formed between the second and third p-electrode layers 54 and 55. More particularly, the reflection layer 57A made of a highly reflective metal such as silver (Ag) is formed on the second electrode layer 54 in order to reflect light emitted from the light emitting layer 13, and the protecting layer 57B made of barrier metal (e.g., Pt) is formed between the reflection layer 57A and the third p-electrode layer 55.

For example, the second p-electrode layer 54 (barrier metal layer), the reflection layer 57A, the protecting layer 57B and the third p-electrode layer 55 (pad electrode) were laminated in sequential order to form Rh/Ag/Rh/Au layers with thicknesses of 30 nm/100 nm/60 nm/1000 nm, respectively, thus completing a p-side electrode. The reflection layer 57A may be formed using Al, Rh, etc. with high reflectivity, other than Ag. Since Rh serves as a barrier layer, using Rh as the second p-electrode layer (barrier layer) enables simple configuration of a laminate structure.

According to the third embodiment of the present invention, similar to the first embodiment and the second embodiment, Ni was deposited to an average layer thickness of 10 nm in island-form and/or mesh-form. The diameters of the islands were in the range Φ10 nm to Φ100 nm and annealed at 400° C. for 10 seconds under a reductive atmosphere, and the second p-electrode layer 54 (barrier layer) was formed after annealing. Therefore, the first p-electrode layer 53 was formed according to the same procedures described in the first embodiment and the second embodiment wherein a mixture region 53A was formed by annealing at a boundary region between the p-type ZnO-based crystal layer 14 and the deposited Ni islands, while maintaining a pure metal layer (Ni layer) 53B on a surface of the first p-electrode layer 53.

After formation of the p-side electrode 52, the device-layer-formed substrate 17 was polished and an n-side electrode 58 was formed. The completed substrate 17 after forming the n-side electrode 58 was divided into separate LEDs by scribing and breaking.

According to the third embodiment, since the p-side electrode 52 is formed on the entire surface of the p-type ZnO-based crystal layer 14, an electrode with further low resistance ohmic characteristics can be achieved. Since current injected into the p-side electrode 52 is diffused throughout a light emitting layer 13, a light emitting device having uniform current injection and high light emission efficiency can be provided. In addition, electrode adhesion properties and bonding strength can be improved.

Although the above-described embodiments described in detail an LED as an illustrative example of a semiconductor light emitting device, the present invention may also be applied to other semiconductor devices such as a semiconductor laser and other electronic devices.

Furthermore, the foregoing exemplary embodiments may also be used as a combination thereof. For example, in the first embodiment and the second embodiment, a reflection layer and a protecting layer may be formed between the second p-electrode layer and the third p-electrode layer.

As described above, the present invention can provide a method for forming a contact electrode with excellent ohmic characteristics as well as high electrode adhesion properties and bonding strength, a ZnO-based compound semiconductor device having the contact electrode and a method for manufacturing the same.

The invention has been described with reference to the preferred embodiments thereof. It should be understood by those skilled in the art that a variety of alterations and modifications may be made from the embodiments described above. It is therefore contemplated that the appended claims encompass all such alterations and modifications.

This application is based on Japanese Patent Application P2009-096485 which is hereby incorporated by reference.

What is claimed is:

1. A method of manufacturing a zinc oxide based (ZnO-based) semiconductor device having at least p-type ZnO-based semiconductor layer, comprising:
a first metal layer formation step of forming a first metal layer on the p-type ZnO-based semiconductor layer in island-form and/or mesh-form wherein the first metal layer contains at least one of nickel (Ni) and copper (Cu);
a heat treatment step of performing heat treatment of the first metal layer and the p-type ZnO-based semiconductor layer under an oxygen-free atmosphere to form a mixture layer comprising elements of the p-type ZnO-based semiconductor layer and the first metal layer at a boundary region between the p-type ZnO-based semiconductor layer and the first metal layer while maintaining a metal phase layer on a surface of the first metal layer; and
a second metal layer formation step of forming a second metal layer so as to cover the first metal layer and the exposed portions of the p-type ZnO-based semiconductor layer through openings of the first metal layer, the second metal layer comprising at least one of Pt (platinum), Rh (rhodium), Pd (palladium) and Ir (iridium).

2. The method according to claim 1, wherein the oxygen-free atmosphere is any one of vacuum, an inert gas atmosphere, a reductive gas atmosphere, and a mixture of an inert gas and a reductive gas.

3. The method according to claim 1, wherein the second metal layer formation step is performed after performing the heat treatment.

4. The method according to claim 1, wherein the heat treatment is performed at a temperature in the range of 350° C. to 450° C.

5. The method according to claim 1, wherein the first metal layer has an average layer thickness in the range 3 nm to 15 nm.

6. The method according to claim 1, wherein the area coverage of the first metal layer on the p-type ZnO-based semiconductor layer is in the 20% to 80% range.

7. The method according to claim 1, wherein the ZnO-based semiconductor device is a light emitting diode (LED) including an n-type ZnO-based semiconductor layer and a light emitting layer.

8. A ZnO-based semiconductor device having at least p-type ZnO-based semiconductor layer, comprising:
a first metal layer formed on the p-type ZnO-based semiconductor layer in island-form and/or mesh-form wherein the first metal layer contains at least one of nickel (Ni) and copper (Cu); and
a second metal layer formed so as to cover the first metal layer and the exposed portions of the p-type ZnO-based semiconductor layer through openings of the first metal layer, the second metal layer comprising at least one of Pt (platinum), Rh (rhodium), Pd (palladium) and Ir (iridium);
wherein the first metal layer includes:
a mixture layer comprising elements of the p-type ZnO-based semiconductor layer and the first metal layer, the mixture layer being formed between the boundary of the p-type ZnO-based semiconductor layer and the first metal layer; and
a metal phase layer formed on the surface of the first metal layer.

9. The ZnO-based semiconductor device according to claim 8, wherein the first metal layer is formed by heat treatment under an oxygen-free atmosphere.

10. A method for forming a contact electrode for a p-type ZnO-based semiconductor, comprising:
a first metal layer formation step of forming a first metal layer on the p-type ZnO-based semiconductor layer in island-form and/or mesh-form wherein the first metal layer contains at least one of nickel (Ni) and copper (Cu);
a heat treatment step of performing heat treatment of the first metal layer and the p-type ZnO-based semiconductor layer under an oxygen-free atmosphere to form a mixture layer comprising elements of the p-type ZnO-based semiconductor layer and the first metal layer at a boundary region between the p-type ZnO-based semiconductor layer and the first metal layer while maintaining a metal phase layer on a surface of the first metal layer; and
a second metal layer formation step of forming a second metal layer so as to cover the first metal layer and the exposed portions of the p-type ZnO-based semiconductor layer through openings of the first metal layer, the second metal layer comprising at least one of Pt (platinum), Rh (rhodium), Pd (palladium) and Ir (iridium).

11. The method according to claim 10, wherein the oxygen-free atmosphere is any one of vacuum, an inert gas atmosphere, a reductive gas atmosphere, and a mixture of an inert gas and a reductive gas.

12. The method according to claim 10, wherein the heat treatment is performed at a temperature in the range of 350° C. to 450° C.
